(19) United States
(12) Patent Application Publication
(10) Pub. No.: US 2024/0071790 A1
(43) Pub. Date: Feb. 29, 2024

(54) MULTI-FUNCTION DEVICE

(71) Applicant: KULICKE AND SOFFA HI-TECH CO., LTD., New Taipei City (TW)

(72) Inventors: Lu-Min Chen, Taipei City (TW); Tsung-Lin Tsai, Taipei City (TW)

(21) Appl. No.: 17/953,128

(22) Filed: Sep. 26, 2022

(30) Foreign Application Priority Data
Aug. 23, 2022 (TW) 111131605

(51) Int. Cl. H01L 21/67

(52) U.S. Cl. CPC H01L 21/67155

(57) ABSTRACT

A multi-function device includes a machine base, a plurality of horizontal bars, at least one gantry, a plurality of processing units and at least one first conveying uni. The horizontal bars are disposed at the top of the machine base. The gantry is disposed on the machine base and disposed over the horizontal bars. The processing unit is disposed on the horizontal bars and the gantry. The first conveying unit is disposed on the machine base. Each processing unit is a processing device capable of being replaced according to actual requirements, such as a soldering flux device, a soldering device, a sucking device, a glue dipping device, a glue dispensing device, a detecting device, a cleaning device or other processing devices. The present invention can integrate different types of manufacturing devices into one device, and the quantities of the horizontal bars and the modules thereof are not limited.

### BACKGROUND OF THE INVENTION

### 1. Field of the Invention

The present invention relates to a multi-function device, in particular to a device integrating different types of machines with each other and having the extension function.

### 2. Description of the Prior Art

A currently available wafer (chip) bonding device includes a machine base, a substrate conveying unit, a wafer conveying unit, a first horizontal bar, a second horizontal bar, a gantry, a visual unit, a pressing unit, a glue dispensing unit, a picking and placing unit, a pushing unit and a detecting unit.

The substrate conveying unit is disposed on the machine base. The wafer conveying unit is disposed in the machine base and adjacent to the substrate conveying unit. The first horizontal bar and the second horizontal bar are disposed on the machine base, and are disposed over the substrate conveying unit. The gantry is installed on the machine base, and disposed over the first horizontal bar and the second horizontal bar. The visual unit and the pressing unit are installed on the gantry. The glue dispensing unit is disposed at one side of the first horizontal bar facing the second horizontal bar. The pushing unit is disposed under the wafer conveying unit. The detecting unit is disposed at one side of the second horizontal bar not facing the first horizontal bar. The substrate conveying unit, the wafer conveying unit, the visual unit, the pressing unit, the glue dispensing unit, the picking and placing unit, the pushing unit and the detecting unit are the elements already known by those skilled in the art, so will not be described herein.

The substrate conveying unit conveys a substrate to the position under the glue dispensing unit, so that the glue dispensing unit dispenses the glue at the target place of the substrate. The visual unit performs visual detection to detect the substrate to detects the position of the target place of the substrate. After the glue dispensing process is completed, the substrate conveying unit conveys the substrate to the position under the picking and placing unit. Visual detection is a common knowledge in the art, so the detailed thereof will not be described herein.

The wafer conveying unit conveys the wafers, processed by the cutting process, to the position over the pushing unit. The visual unit executes visual detection to detect the substrate so as to determine the die to be moved. The pushing unit pushes the die to be moved according to the visual or program settings of the visual unit. The picking and placing unit picks the die via vacuum suction and places the die at the target place.

The pressing unit then presses the die and the substrate. The substrate conveying unit conveys the pressed substrate to the detecting unit, so that the detecting unit detects the pressing status of the substrates. The wafer conveying unit, the visual unit, the pressing unit, the glue dispensing unit, the picking and placing unit, the pushing unit and the detecting unit repeat the above-mentioned steps.

The above bonding device can effectively complete the bonding operation of the die and the substrate. However, the currently available bonding device can only perform bonding operation, but cannot implement other manufacturing processes. However, with high development of electronic products, the manufacturers need to purchase more machines designed for different manufacturing processes, which may increase various costs in factories, manpower, equipment, etc.

Thus, it has become an important issue to develop a bonding device conforming to the requirements of various manufacturing processes and having extension function.

### SUMMARY OF THE INVENTION

In order to solve the above problems of prior art, the inventor of the present invention has conducted research and experiments for many years. Finally, the inventor of the present invention successfully develops a multi-function device.

To achieve the foregoing objective, the present invention provides a multi-function device, which includes a machine base, a plurality of horizontal bars, at least one gantry, a plurality of processing units and at least one first conveying unit. The horizontal bars are disposed at the top of the machine base. The gantry is disposed on the machine base and disposed over the horizontal bars. The processing units are disposed at the horizontal bars and the gantry respectively. The first conveying unit is disposed on the machine base.

In one embodiment of the present invention, the multi-function device further includes at least one second conveying unit disposed on the machine base and adjacent to the horizontal bars.

In one embodiment of the present invention, the first conveying unit includes an inching rail, at least one inching gripper and a conveying platform. The conveying platform is disposed on the machine base and under the horizontal bars. The inching rail is disposed on the machine base and linked to the conveying platform. The inching gripper is disposed between the horizontal bars and the inching gripper is linked to the inching rail.

In one embodiment of the present invention, the processing unit is at least one of a pressing device, a soldering flux device, a soldering device, a sucking device, a glue dipping device, a glue dispensing device, a detecting device and a cleaning device.

In one embodiment of the present invention, the multi-function device further includes an extended processing unit disposed on the machine base and between the horizontal bars. The extended processing unit is a cleaning device.

In one embodiment of the present invention, the multi-function device further includes a bottom processing unit disposed on the machine base and under the second conveying unit.

In one embodiment of the present invention, the first conveying unit is a substrate conveying device, the second conveying unit is a wafer conveying device or a die tray conveying device. The bottom processing unit is a pushing device.

In one embodiment of the present invention, each of the processing units includes a visual unit disposed on the gantry.

In one embodiment of the present invention, each of the processing unit has a visual module.

In one embodiment of the present invention, the multi-function device includes at least one assistant processing unit disposed at one side or one end of the machine base. The assistant processing unit is a material feeding device.

Via the above invention, each processing unit can be replaced by a desired processing device according to actual requirements, such as a soldering flux device, a soldering device, a sucking device, a glue dipping device, a glue dispensing device, a detecting device, a cleaning device or other processing devices. The present invention can integrate different types of manufacturing devices into one device, and the quantities of the horizontal bars and the modules thereof are not limited. The present invention can also be customized to include more processing devices, gantries, bars, first conveying units, bottom processing units and second conveying units. Therefore, the present invention can reduce various costs in factories, manpower, equipment, etc.

### BRIEF DESCRIPTION OF THE DRAWINGS

For a better understanding of the aforementioned embodiments of the invention as well as additional embodiments thereof, reference should be made to the Description of Embodiments below, in conjunction with the following drawings in which like reference numerals refer to corresponding parts throughout the figures.

FIG. 1 is a top view of a multi-function device in accordance with a first embodiment of the present invention.

FIG. 2 is a front view of the multi-function device in accordance with the first embodiment of the present invention.

FIG. 3 is a sectional view of a section A-A shown in FIG. 2 of the multi-function device in accordance with the first embodiment of the present invention.

FIG. 4 is a sectional view of a section B-B shown in FIG. 2 of the multi-function device in accordance with the first embodiment of the present invention.

FIG. 5 is a 3D schematic view of an appearance of a multi-function device in accordance with a second embodiment of the present invention.

### DETAILED DESCRIPTION OF THE PREFERRED EMBODIMENT

The following description is about embodiments of the present invention; however it is not intended to limit the scope of the present invention.

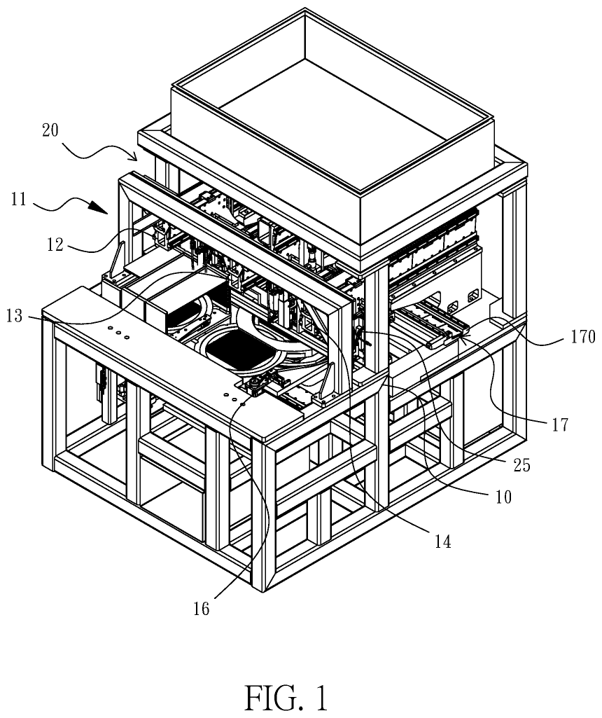

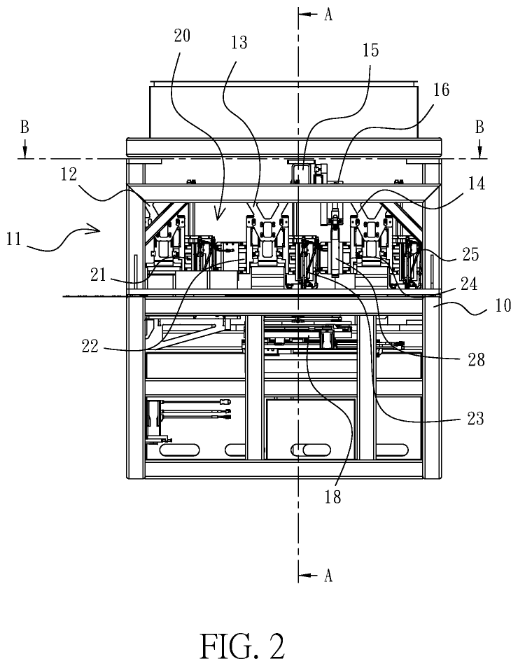

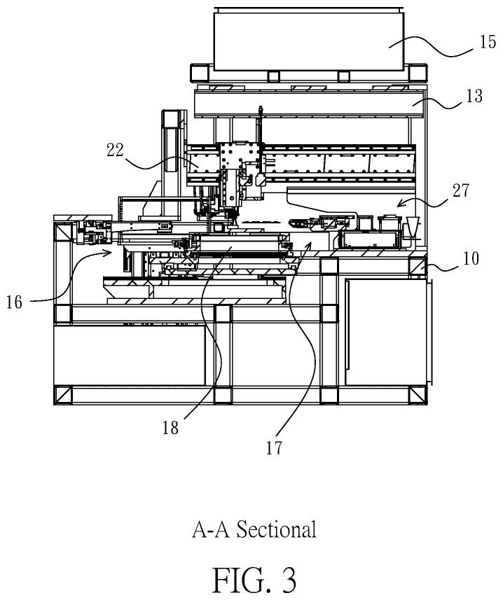

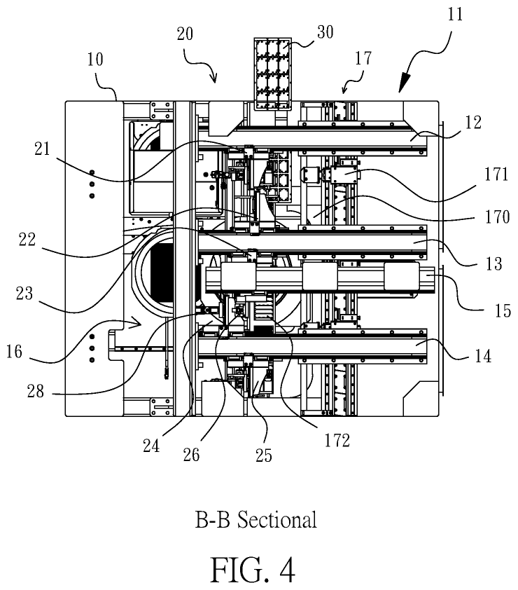

Please refer to FIG. 1, FIG. 2, FIG. 3 and FIG. 4. FIG. 1 is a top view of a multi-function device in accordance with a first embodiment of the present invention. FIG. 2 is a front view of the multi-function device in accordance with the first embodiment of the present invention. FIG. 3 is a sectional view of a section A-A shown in FIG. 2 of the multi-function device in accordance with the first embodiment of the present invention. FIG. 4 is a sectional view of a section B-B shown in FIG. 2 of the multi-function device in accordance with the first embodiment of the present invention. As shown in FIG. 1 to FIG. 4, the multi-function device includes a machine base 10, a plurality of horizontal bars 11, at least one gantry 15, at least one second conveying unit 16, at least one first conveying unit 17, at least one bottom processing unit 18, a plurality of processing units 20, at least one extended processing unit 27 and at least one visual unit 28.

The quantity of the horizontal bars 11 can be increased according to the requirements of the manufacturer. In the embodiment, the horizontal bars 11 include a first horizontal bar 12, a second horizontal bar 13 and a third horizontal bar 14, which are orderly arranged to form a row, and disposed at the top of the machine base 10. The horizontal bars 11 can also be arranged to form several rows and disposed at the top of the machine base 10.

The gantry 15 is movable and disposed on the machine base 10. The gantry 15 is disposed over the horizontal bars 11. In the embodiment, the gantry 10 is disposed over the first horizontal bar 12, the second horizontal bar 13 and the horizontal bar 14.

The second conveying unit 16 is disposed on the machine base 10 and adjacent to the horizontal bars 11. In the embodiment, the second conveying unit 16 is adjacent to the first horizontal bar 12, the second horizontal bar 13 and the third horizontal bar 14. The bottom processing unit 18 is disposed on the machine base 10 and under the second conveying unit 16.

The first conveying unit 17 is disposed on the machine base 10. In the embodiment, the first conveying unit 17 is an inching device. The first conveying unit 17 includes an inching rail 170, at least one inching gripper 171 and a conveying platform 172.

The conveying platform 172 is disposed on the machine base 10 and under the horizontal bars 11. In the embodiment, the conveying platform 172 is disposed under the first horizontal bar 12, the second horizontal bar 13 and the third horizontal bar 13.

The inching rail 170 is disposed on the machine base 10. The inching rail 170 is under the horizontal bars 11 and adjacent to the conveying platform 172. In the embodiment, the inching rail 170 is under the first horizontal bar 12, the second horizontal bar 13 and the third horizontal bar 14, and adjacent to the conveying platform 172. The inching rail 170 is linked to the conveying platform 172.

The inching gripper 171 is disposed between the horizontal bars 11. In the embodiment, the inching gripper 171 is disposed at the side, facing the second horizontal bar 13, of the first horizontal bar 12. The inching gripper 171 is linked to the inching rail 170. Another inching gripper (not shown in the drawings) is disposed at the side, facing the third horizontal bar 14, of the second horizontal bar 13 or the side, not facing the second horizontal bar 13, of the third horizontal bar 14. The inching gripper 171 can drive the inching rail 171 to move and the moving inching rail 171 can further drive the conveying platform 172. The detailed structures of the inching device, the inching rail 170, the inching gripper 171 and the conveying platform 172 are already known by those skilled in the art, so will not be described herein.

The processing unit 20 is disposed on the horizontal bars 11 and the gantry 15. The processing units 20 may include a first processing unit 21, a second processing unit 22, a third processing unit 23, a fourth processing unit 24, a fifth processing unit 25 and a sixth processing unit 26.

In the embodiment, the first processing unit 21 is disposed at one side, facing the second horizontal bar 13, of the first processing unit 12. The first processing unit 21 includes a first visual module (not shown in the drawings). The second processing unit 22 is disposed at one side, facing the first horizontal bar 12, of the second horizontal bar 13. The second processing unit 22 includes a second visual module (not shown in the drawings). The third processing unit 23 is disposed at one side, facing the third horizontal bar 14, of the second horizontal bar 13. The third processing unit 23 includes a third visual module (not shown in the drawings). The fourth processing unit 24 is disposed at the side, facing the second horizontal bar 13, of the third horizontal bar 14. The fourth processing unit 24 includes a fourth visual module (not shown in the drawings). The fifth processing unit 25 is disposed at the side, not facing the second horizontal bar 13, of the third horizontal bar 14. The fifth processing unit 25 includes a fifth visual module (not shown in the drawings).

The first processing unit 21, the second processing unit 22, the third processing unit 23, the fourth processing unit 24, the fifth processing unit 25 and the sixth processing unit 26 can selectively move in x-axis direction, y-axis direction and z-axis direction, in relative to the machine base 10, respectively. The first processing unit 21, the second processing unit 22, the third processing unit 23, the fourth processing unit 24, the fifth processing unit 25 and the sixth processing unit 26 may be at least one of pressing devices, soldering flux devices, soldering devices, sucking devices, glue dipping devices, glue dispensing devices, detecting devices, cleaning devices and other relevant processing devices. The detailed structures of pressing devices, soldering flux devices, soldering devices, sucking devices, glue dipping devices, glue dispensing devices, detecting devices, cleaning devices and other relevant processing devices are already known by those skilled in the art, so will not be described herein.

The extended processing unit 27 is disposed on the machine base 10. The extended processing unit 27 is disposed between the horizontal bars 11 and adjacent to the inching rail 170. In the embodiment, the extended processing unit 27 is disposed between the second horizontal bar 13 and the third horizontal bar 14. In addition, the extended processing unit 27 is adjacent to the inching rail 170. Moreover, the extended processing unit 27 can be disposed between the first horizontal bar 12 and the second horizontal bar 13 according to actual requirements.

The extended processing unit 27 may be a cleaning device, which includes a weighting module, volume measuring module, a viscosity measuring module or glue cleaning module. When the above glue dispensing device is contaminated or the quality of the glue is low, the glue dispensing device moves toward the direction of the extended processing unit 27 (the cleaning device) to reach the position over the weighting module. The glue dispensing needle of the glue dispensing device dispenses the glue on the weighting module, the weighting module measures the weight of the glue. If the weight of the glue exceeds or is less than a predetermined weight, the glue dispensing device can adjust the weight of the glue outputted from the glue dispensing needle according to the feedback of the weighting module. Similarly, the cleaning device can dispense the glue on the volume measuring module or the viscosity measuring module. If the volume or the viscosity of the glue fails to conform to the desired setting, the user can adjust which according to the value of the feedback. If the glue dispensing needle of the glue dispensing device is contaminated, the glue dispensing needle can be cleaned via the cleaning module. After the cleaning process is finished, the glue dispensing device can return to the operational position (the initial position where the glue is dispensed). The detailed structures of the weighting module, the volume measuring module, the viscosity measuring module and the cleaning module are already known by those skilled in the art, so will not be described herein.

The visual unit 28 and the sixth processing unit 26 are disposed on the gantry 15. The visual unit 28 is adjacent to the sixth processing unit 2.

In one embodiment, the first processing unit 21 is a soldering flux device. The second processing unit 22 is a soldering device. The third processing unit 23 is a glue dispensing device. The fourth processing unit 24 is a picking and placing device. The fifth processing unit 25 is a detecting device. The sixth processing unit 26 is a pressing device. The extended processing unit 27 is a cleaning device. The second conveying unit 16 is a wafter conveying device or a die tray conveying device. The bottom processing unit 18 is a pushing device. The first conveying unit 17 is a substrate conveying device.

A plurality of substrates 30 or at least one substrate 30 is disposed on the conveying platform 172. The inching gripper 171 drives the inching rail 170 and then the moving inching rail 170 further drives the conveying platform 172, such that the conveying platform 170 conveys the substrate 30 to the first processing unit 21. The first visual module 210 performs visual orientation for the substrate 30. The detailed operation of the visual orientation is already known by those skilled in the art, so will not be described herein.

The first processing unit 21 outputs the soldering flux on the target place of the substrate 30 according to the result of the visual orientation of the first visual module. Afterward, the conveying platform 172 conveys the substrate 30 with the soldering flux to the second processing unit 22.

The second visual module executes visual orientation for the substrate 30 with the soldering flux. The second processing unit 22 performs soldering for the substrate 30 with the soldering flux according to the result of the visual orientation of the second visual module. After the soldering process is finished, the conveying platform 172 conveys the substrate 30 to the third processing unit 23.

The third visual module performs visual orientation for the substrate 30 to be bonded. The third processing unit 23 dispenses the glue on the substrate 30 according to the result of the visual orientation of the third visual module. After the glue dispensing process is finished, the conveying platform 172 conveys the substrate to the fourth processing unit 24. If the glue dispensing needle of the third processing unit 23 is contaminated during the glue dispensing process, the third processing unit 23 moves to the extended processing unit 27 so as to execute the relevant cleaning process. After the third processing unit 23 is cleaned, the third processing unit 23 returns to the initial position again so as to implement the relevant processing process.

The second conveying unit 16 can convey the wafer which has been processed by the cutting process or the tray where the dies are disposed. In the embodiment, the second conveying unit 16 conveys the wafer which has been processed by the cutting process to the fourth processing unit 24. The fourth visual module 240 determines the position of at least one die, disposed on the second conveying unit 16, to be moved and the position of at least one substrate 30, disposed on the conveying platform 172, with the glue respectively. The bottom processing unit 18 pushes the die to be moved according to the result of the visual orientation of the fourth visual module. The fourth processing unit 24 takes the die pushed by the bottom processing unit 18 via vacuum suction or a robotic arm, and places the die on the substrate 30 with the glue.

After the die is placed on the substrate 30, the visual unit 28 performs visual orientation for the die and the substrate 30, the sixth processing unit 26 performs pressing for the die and the substrate 30 according to the result of the visual orientation of the visual unit 28. After the pressing process is finished, the conveying platform 172 conveys the substrate 30 which has been pressed to the fifth processing unit 25.

The fifth visual module executes visual orientation for the substrate 30 on the conveying platform 172. The fifth processing unit 25 detects the substrate 30 according to the result of the visual orientation. After the detecting process is finished, the conveying platform 172 conveys the substrate 30 to another position in order to perform another manufacturing process.

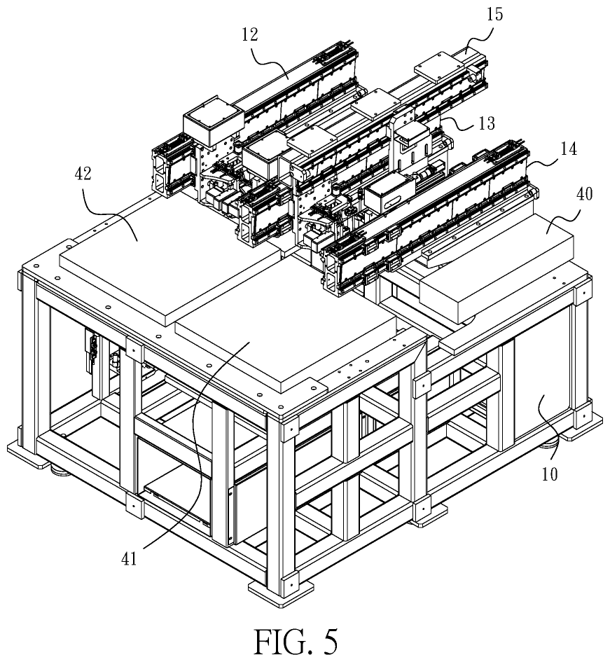

Please refer to FIG. 5, which is a 3D schematic view of an appearance of a multi-function device in accordance with a second embodiment of the present invention. As shown in FIG. 5, one end and/or one side of the machine base 10 is provided with at least one assistant processing unit. In the embodiment, the assistant processing unit may be a first assistant processing unit may be a first assistant processing unit 40, a second assistant processing unit 41 and a third assistant processing unit 42. The first assistant processing unit 40 is disposed at one side, not facing the second horizontal bar 13, of the third horizontal bar 14. The second assistant processing unit 41 and the third assistant processing unit 42 are disposed at one end of the first horizontal bar 12, one end of the second horizontal bar 13 and one end of the third horizontal bar 14. The assistant processing units may be feeding belts, feeding trays or vibration trays for material feeding. Thus, each assistant processing unit may be considered a material feeding device.

To sum up, the quantities of the processing units 20, the gantry 15, the horizontal bars 11, the first conveying units 17, the bottom processing unit 18 and the second conveying unit 16 can be adjusted according to actual requirements. Each of the processing units 20 can be replaced by a desired processing device, such as a soldering flux device, a soldering device, a sucking device, a glue dipping device, a glue dispensing device, a detecting device and a cleaning device or other processing device. The present invention can integrate different types of manufacturing devices into one device, and the quantities of the horizontal bars and the modules thereof are not limited. The present invention can also be customized to include more processing devices, gantries 15, bars 11, first conveying units 17, bottom processing units 18 and second conveying units 16. Therefore, the present invention can reduce various costs in factories, manpower, equipment, etc.

The above disclosure is related to the detailed technical contents and inventive features thereof. Those skilled in the art may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A multi-function device, comprising:
a machine base;
a plurality of horizontal bars disposed at a top of the machine base;
at least one gantry disposed on the machine base and disposed over the horizontal bar;
a plurality of processing units disposed on the horizontal bars and the gantry; and
at least one first conveying unit disposed on the machine base.

2. The multi-function device of claim 1, further comprising at least one second conveying unit disposed on the machine base and adjacent to the horizontal bars.

3. The multi-function device of claim 1, wherein the first conveying unit comprises an inching rail, at least one inching gripper and a conveying platform, wherein the conveying platform is disposed on the machine base and under the horizontal bars, and the inching rail is disposed on the machine base and linked to the conveying platform, wherein the inching gripper is disposed between the horizontal bars and the inching gripper is linked to the inching rail.

4. The multi-function device of claim 1, wherein the processing unit is at least one of a pressing device, a soldering flux device, a soldering device, a sucking device, a glue dipping device, a glue dispensing device, a detecting device and a cleaning device.

5. The multi-function device of claim 1, further comprising an extended processing unit disposed on the machine base and between the horizontal bars, wherein the extended processing unit is a cleaning device.

6. The multi-function device of claim 2, further comprising a bottom processing unit disposed on the machine base and under the second conveying unit.

7. The multi-function device of claim 6, wherein the first conveying unit is a substrate conveying device, the second conveying unit is a wafer conveying device or a die tray conveying device, and the bottom processing unit is a pushing device.

8. The multi-function device of claim 1, further comprising a visual unit disposed on the gantry.

9. The multi-function device of claim 4, wherein each of the processing unit has a visual module.

10. The multi-function device of claim 1, further comprising at least one assistant processing unit disposed at one side or one end of the machine base, wherein the assistant processing unit is a material feeding device.
